(19) United States
(12) Patent Application Publication
(10) Pub. No.: US 2014/0092521 A1
(43) Pub. Date: Apr. 3, 2014

(54) METHOD AND EQUIPMENT FOR QUANTUM VACUUM ENERGY EXTRACTION

(71) Applicant: Charles Hillel ROSENDORF, West Orange, NJ (US)

(72) Inventor: Charles Hillel ROSENDORF, West Orange, NJ (US)

(21) Appl. No.: 13/632,068

(22) Filed: Sep. 30, 2012

(51) Int. Cl. H05F 3/00; H05K 13/00; B82Y 99/00

(52) U.S. Cl. 361/233; 29/592.1; 977/948; 977/734; 977/742

(57) ABSTRACT

Embodiments of the present invention comprise different methods and equipment for efficiently and relatively inexpensively producing Casimir cavities for use in quantum vacuum energy extraction. The methods include without limitation, sintering; submicron porous filter materials; web roll-to-roll produced mesh or foil layers; nanotube arrays; web roll-to-roll produced porous membranes such as graphene, metallically doped; web roll-to-roll produced metallic crystals with self assembling arrays of nano-channels; three-dimensional prototyping; charged particle deposition; metal wire bundles; metal tube bundles; and metallically doped or metallically coated glass or polymer wire bundles.

### CROSS-REFERENCE TO RELATED APPLICATION

This application claims the benefit of United States Provisional Application For Patent Ser. No. 61/558,738, filed Nov. 11, 2011, and whose contents are incorporated by reference herein in their entirety.

### FIELD OF THE INVENTION

Embodiments of the present invention comprise methods and apparatus for energy extraction from liquids and gases. More specifically, embodiments of this invention comprise methods and apparatus for quantum vacuum energy extraction.

### BACKGROUND OF THE INVENTION

Presently, as energy needs and costs around the world continue to rise, development of energy resources which are widely available, reasonably priced, and non-polluting is a top priority in many places worldwide.

One potential significant energy source is quantum vacuum energy extraction. This potential energy source is currently the subject of much research and discussion.

Quantum vacuum energy extraction is a source of energy resulting from the zero-point radiation field. The relevant prior art contains a number of theoretical discussions of this phenomenon, including without limitation:
(1) Boyer, T. H., 1975, “Random Electrodynamics: The Theory of Classical Electrodynamics with Classical Zero-Point Radiation Field” (Phys. Rev. D, 11, 790);
(2) Cole, D. C. and Puthoff, H. E., 1993, “Extracting energy and heat from the vacuum” (Phys. Rev. E., 48, 2, 1562; and
(3) Moddel, G. 2010, “A Demon, a Law, and the Quest for Virtually Free Energy” (Edge Science, January-March, No. 2, 10.
Further, U.S. Pat. No. 7,379,286, issued May 27, 2008 to Haisch, et al., and titled “Quantum Vacuum Energy Extraction” (“Haisch et al.” or the “286 Patent”) describes this phenomenon in detail. The Abstract of the '286 patent explains quantum vacuum energy extraction:
   A system is disclosed for converting energy from the electromagnetic quantum vacuum available at any point in the universe to usable energy in the form of heat, electricity, mechanical energy or other forms of power. By suppressing electromagnetic quantum vacuum energy at appropriate frequencies a change may be effected in the electron energy levels which will result in the emission or release of energy. Mode suppression of electromagnetic quantum vacuum radiation is known to take place in Casimir cavities. A Casimir cavity refers to any region in which electromagnetic modes are suppressed or restricted. When atoms enter into suitable micro Casimir cavities a decrease in the orbital energies of electrons in atoms will thus occur. Such energy will be captured in the claimed devices. Upon emergence from such micro Casimir cavities the atoms will be re-energized by the ambient electromagnetic quantum vacuum. In this way energy is extracted locally and replenished globally from and by the electromagnetic quantum vacuum. This process may be repeated an unlimited number of times. This process is also consistent with the conservation of energy in that all usable energy does come at the expense of the energy content of the electromagnetic quantum vacuum. Similar effects may be produced by acting upon molecular bonds. Devices are described in which gas is recycled through a multiplicity of Casimir cavities. The disclosed devices are scalable in size and energy output for applications ranging from replacements for small batteries to power plant sized generators of electricity.

The Haisch et al. patent discusses the use of micro-electro-mechanical systems (“MEMS”) for zero point energy extraction. In the electronics fields, such as in the manufacture of semiconductors, the products are becoming smaller and smaller. Consequently, the spacing between components has become reduced as the products become smaller. Movement of either the components of the MEMS device, or of a fluid (a liquid or a gas) within the device, is important to deriving zero point energy from these device.

If the components become too close together in these devices, a problem referred to as “Stiction” occurs, meaning that the movement of the components, or of the fluid between the components, is reduced. For example, MEMS are non-linear three-dimensional surfaces that exhibit stiction if the surfaces are too close together. Thus there is a size balance that has to be struck in order to obtain a properly functioning device which can be utilized for zero point energy production.

Haisch et al. made certain assumptions about the energy that may be obtained from a Casimir cavity-containing device. For example, a device comprising two square parallel plates, each being 10 cm by 10 cm in size, with each plate containing 5000 conducting strips that are 10 microns in width and 10 cm in length, separated by 10 micron non-conducting strips; and perpendicular to the strips a plurality of spacer material at 0.1 to 1 cm intervals with a height of 0.1 microns, when the plates are put face to face and the strips aligned, the device contains 5000 Casimir strips.

Assuming a gas flow rate of 10 cm/s parallel to the spacers and perpendicular to the strips, this would result in 1.3×10²⁰ transitions/s.

An assumed energy release of 1 to 10 eV per transition corresponds to 21 to 210 watts of energy release for the entire Casimir cavity. A stacked set of 10 or more such layers may be fabricated yielding 210 to 2100 watts for a 10×10×10 cm block.

This reference also makes other assumptions concerning the power that may be generated from different devices containing Casimir cavities, or from different types of actions used to cause fluid to flow through such devices. Haisch et al. provide data about the amount of energy needed to make a system operational, concluding that the energy output will be greater than the energy input.

At present, there are no viable commercialized systems for extracting this energy. It is believed that this lack of commercialization may primarily be due to the costs of fabricating the systems disclosed in the '286 patent (see e.g., '286 patent, 11:29-58 and 14:1-21.

It would greatly increase the viability of this energy source to have a less costly method and system of fabricating the Casimir cavities that may be used for zero point energy extraction. Embodiments of the present invention may utilize commercially available as well as custom fabricated components for construction of Casimir cavities in devices that may be scalable in size and energy output, and for applications ranging from replacements for small batteries to power plant-sized generators of electricity.

### BRIEF SUMMARY OF THE INVENTION

An object of the present invention is a method of fabricating Casimir cavities that may allow for economical and viable commercialization of quantum vacuum energy extraction.

Another object of the present invention is a system of fabricating Casimir cavities that may allow for economical and viable commercialization of quantum vacuum energy extraction.

In short, embodiments of the present invention comprise different techniques for efficiently and relatively inexpensively producing Casimir cavities that may be used for quantum vacuum energy extraction.

Embodiments of the present invention may utilize commercially available as well as custom fabricated components for construction of Casimir cavities in devices that may be scalable in size and energy output, and for applications ranging from replacements for small batteries to power plant-sized generators of electricity.

### BRIEF DESCRIPTION OF THE SEVERAL VIEWS OF THE DRAWING

FIG. 1 is a schematic illustration of a Casimir device comprising a plurality of roll-to-roll web processed foils of a material overlaid on each other, such as metallically doped graphene, and with a compact laser array being utilized to create a plurality of Casimir Effect pore sized openings in the device perpendicular to the plane of the layered foils.

FIG. 2 is a schematic illustration of a water-jacketed chamber used to contain the device of FIG. 1. The arrows indicate the direction of liquid flow through the water jacket.

FIG. 3 illustrates the use of wire bundles for Casimir cavity formation.

FIG. 4 illustrates the use of wires in non-linear arrays for Casimir cavity formation.

FIG. 5a illustrates a flanged opening in a foil.

FIG. 5b is a cross-section of the flanged opening of FIG. 5A taken along line 5-5.

FIG. 6 illustrates the use of tube bundles for Casimir cavity formation.

### DETAILED DESCRIPTION OF THE INVENTION

Embodiments of the present invention comprise different techniques and devices for efficiently and relatively inexpensively producing Casimir cavities in an efficient and relatively inexpensive manner. For purposes of the present specification, the term “fluid” is intended to encompass fluids such as gases and liquids. A non-limiting example is the monoatomic noble gases, although other gases may be utilized. As will be described further, energy extraction occurs with the passage of a fluid through the Casimir cavity-containing devices.

A general concept of the present invention is that a gas that is in equilibrium with the ambient electromagnetic modes, which include the vacuum field (also known as a zero point field), is caused to enter a Casimir cavity. For the purposes of the present specification, the term “Casimir cavity” will refer to any region in which the electromagnetic modes are restricted. Upon approaching this region, the electromagnetic modes that the space supports are restricted and the energy of the electron orbitals of the fluid's atoms is reduced. As a consequence of this reduction the excess energy is emitted and absorbed by the apparatus, providing the energy. By the time the atoms are in the Casimir cavity nearly all the excess energy has been radiated (unless the fluid flow is extremely fast). The gas atoms pass through the Casimir cavity, and upon emerging from this region to a region that supports a broader range of electromagnetic modes, the energy of the electron orbitals of the gas atoms is again allowed to rise to its previous value. The compensation for the energy deficit is provided from the ambient electromagnetic modes.

All of the embodiments comprise two circuits. One circuit provides for quantum vacuum energy extraction. The fluid in this circuit circulates and recirculates through a plurality of Casimir cavities. Circulation may be accomplished by a pump, an oscillating motor, or other means known in the art.

A second circuit provides for thermal extraction from the fluid of energy (most commonly, but not limited to, heat) gained by the fluid during quantum vacuum energy extraction. This extraction (thermal or otherwise) is described further below.

As will be described herein, devices containing Casimir cavities can be manufactured using a variety of methods and a variety of materials, ranging from, for example only, carbon based structures, foils of metallic or semi-conductor materials, and polymers of organic or inorganic origin, examples of which follow.

### Sintering

One embodiment for producing Casimir cavities comprises metal sintering. Sintering, or powder technology, is a well-known technique for fabricating porous materials. By choosing materials having the desired characteristics and utilizing one or more methods, a sintering process may be chosen to produce Casimir cavities having the desired purity, porosity, and conductivity properties usable for quantum vacuum energy extraction. (See “Porous Metal Design Guidebook”, the contents of which are incorporated by reference herein, from Metal Powder Industry Foundation, Princeton N.J., 2007 www.mpif.org).

Porous sintered metals are known to those skilled in the art for such purposes as filters for use with liquids and gases, for components involved in fluid flow metering and pressure control, as storage reservoirs for liquids, flame and spark arrestors for the safe handling of flammable gases, devices for sound dampering and attenuation, in gas distribution and sparging devices, and for media retention, such as in permeable barriers for desiccants.

A variety of metals can be utilized for metal sintering, and some of the more commonly used ones include, without limitation, stainless steel, such as Type 316L stainless; bronze; nickel; nickel based alloys such as MonelT™, Inconel™ or Haynes™, (registered trademarks of Inco, Ltd.), titanium, copper, aluminum, gold, silver, various other precious metals, individually or in combination. Bronzes can include metals with differing ratios of copper and tin. While the metals listed above are illustrative examples, almost any substance can be obtained in a powder form, such that any material can be obtained through sintering, although material selection can be affected by both the cost of the materials and the processes that may be used.

### Axial Compacting and Sintering

One method of preparing a sintered metal involves the process of axial compacting and sintering. In this process, the metal powder is pressed in a die at a pressure that is sufficient for the powder particles to adhere at their contact points with adequate strength for the formed part to be handled after ejection from the die. The strength of this green (unsintered) product depends on the characteristics of the particular metal powder(s) employed (for example, composition, particle size, shape, purity, etc.), and the pressure under which the product is formed. (Porous metal parts differ from standard porous metal structural parts in that they are pressed at lower pressures and may utilize tight mesh cuts of powder to achieve a specified porosity.) After forming, the green parts are then heated, or sintered, in a controlled atmosphere at a temperature that is below the melting point of the metal, yet still sufficient to bond the particles together, thus markedly increasing the component' strength. Advantages of this process include high production rates, good permeability control and dimensional reproducibility. Non-limiting examples of metals that are most frequently processed by this method include stainless steel, titanium, nickel alloys and some bronze compositions.

### Gravity Sintering

Gravity sintering, also referred to “loose powder” sintering is used to make components from powders that diffusion-bond easily (most production parts are made from bronze). In this process, no outside pressure is applied to shape the part. The appropriate material, graded for size, is poured into a mold cavity, and the metal particles are then heated to their sintering temperature at which point a metallurgical bonding takes place. After the sintering process has been completed and the mold cooled to a temperature at which the mold can be opened and the product handled, the product is removed from the mold and used for further processing.

The inner diameter (“I.D.”) of products formed by gravity sintering tends to be predictable because the material usually shrinks to the core of the mold during sintering. The O.D. (outer diameter) will vary somewhat from piece to piece due to factors such as size, shape, material, density of “fill” material, and the like.

### Powder Rolling and Sintering

Powder rolling and sintering is used to fabricate sheets from metals such as stainless steel, copper, bronze, nickel based alloys and titanium. The sheet material is made by direct powder rolling or by gravity filling of molds (as described in the previous section) and calendaring before sintering. By selecting a metal powder having a particular particle size, a product having a specified porosity can be prepared.

Depending on the metal selected and its density, the processed sheet can be produced in a variety of thickness, from 0.25 mm (0.010″) to 3 mm (0.12″) and in area dimensions up to one square meter or several square feet. The sheet can be sheared, rolled and welded into different configurations.

### Isostatic Compaction and Sintering

Isostatic compaction and sintering applies pressure in a uniform manner to a deformable container holding the metal powder to be compacted. This technique is known to be useful in the manufacturing of parts having a large length-to-diameter ratio, such as tubing, for example.

An isostatic compacting system generally includes a pressure vessel designed to contain a fluid under high pressure, a deformable container and one or more arbors (or cores) if tubes or special shapes are being made. By appropriate choice of pressurizing fluid and containers, the isostatic process can be used at elevated temperatures (Hot Isostatic Pressing), although most porous parts are made at room temperature. The green product, after removal from the isostatic vessel, is sintered in a standard way. The isostatic sintering process may be used with all conventional porous metal materials.

### Metal Spraying

Metal spraying, the process of spraying a molten metal onto a base, can also be used to manufacture metallic products. In this process the spraying conditions, as well as the particular metal chosen, affect the porosity of the end product. A second material can be sprayed onto the base, such as by co-spraying it with the desired metal, and this combination can also effect the desired properties of the final product.

Similarly, one or more metal powders can be mixed with one or more binders to form a slurry that can be applied to porous substrates or used to form net shape components. Special care and equipment is normally required to insure appropriate binder removal and uniform porosity.

### Metal Injection Molding and Sintering

Metal injection molding (“MIM”) and sintering, utilizes one or more metal powders with a quantity of one or more binders to form a viscous material that is subjected to high-pressure injection. Depending on the material characteristics and MIM tool design, components with controlled density can be formed. Special debinding and sintering equipment is required for processing materials by this method because of the large amount of shrinkage that occurs during binder removal.

The metal or combination of metals selected for forming the Casimir cavity needs to be conductive.

Sintering has numerous advantages over other manufacturing processes, including without limitation:

(See http://en.wikipedia.org/wiki/Sintering, “Sintering” as of Nov. 11, 2011).
a. Very high levels of purity and uniformity in starting materials.
b. Preservation of purity, due to the simpler subsequent fabrication process (fewer steps) that it makes possible.
c. Capability to produce materials of controlled, uniform porosity.
d. Capability to produce materials which cannot be produced by any other technology.
e. Capability to sinter dissimilar materials.
f. Components used in various may be shaped, molded, or bent to maximize application dimensional space requirements and Quantum Vacuum Energy Extraction.
g. The design may include alternate layers of conducting and non-conducting materials. The gas atoms or molecules absorb energy from the surrounding electromagnetic field when they are in the non-conducting region and then release a portion of their energy as they enter the gap between the conductive coatings, i.e., in the Casimir cavity.
h. Sheets of thermoelectric materials, of which porous skutterudites are a non-limiting example, or other thermoelectric devices may be layered among or around conducting and non-conducting layers of a sintered array assembly for direct heat to electrical conversion.

Using one or more of the above-referenced methods, metallic structures, such as sheets or tubes of a sintered metal, or other structural configurations, an array of such Casimir cavities are formed, with the Casimir cavities in close proximity to each other, to facilitate quantum vacuum energy extraction. Then, these arrays of Casimir cavity-containing devices are utilized for quantum vacuum energy extraction.

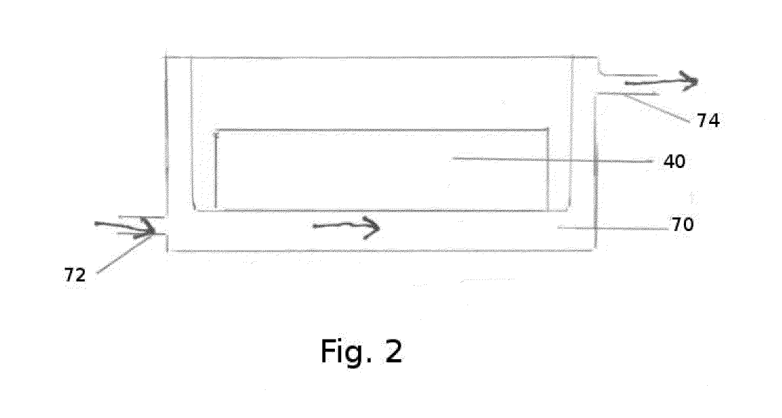

In one embodiment, a plurality of sintered metal filters, or other devices, may be placed in a closed filter holder, the filter holder having inlet and outlet means for a fluid. The apparatus may then be surrounded by a means to capture the released energy, such as a water bath or a water-jacketed chamber 70 (FIG. 2). Water is known to absorb infrared radiation very effectively.

The water jacket 70 may be filled with a heat transfer substance, such as water, and may be connected to a pump via tubing or other means of fluid communication, and connected to another device into which the released energy is transferred. Using the pump, water 72 is circulated around the filter holder 40, during which time the water 72 absorbs the released energy and becomes heated water 74. The heated water 74 may then be circulated to the other device in a continuous loop. Depending upon the operational temperature employed, a heat transfer means other than water may be employed, non-limiting examples of which include any other material or device that absorbs substantially the released energy wavelengths, such as glass, organic polymers, various thermoelectric devices, one non-limiting example of which is a sintered porous skutterudite, thermophotovoltaic devices, and other materials known to those skilled in the art.

The steps in the device fabrication that are not described explicitly are well known to those skilled in the art.

It is to be understood that the dimensions and materials can be varied greatly and still be part of this invention, for example, and not intended as limiting, the following:
i. The substrates may be other insulating or partially conducting materials, such as silicon, glass, ceramic, plastic, etc.
ii. The conducting strips can be formed of other conductors, such as copper, aluminum, gold, silver, platinum, silicides, transparent conductors such as indium tin oxide, etc.
iii. Instead of depositing the strips so that they protrude from the surface and potentially interfere with the gas flow, they may be recessed, either by etching recesses into which the conductors are deposited, or by using planarization techniques to coat an insulating layer between the strips, using techniques known to those skilled in the art.
iv. The spacer materials can be formed from polymers used, for example, as photoresist and electron-beam resist, from metals, and other materials.
v. Spacers may be formed by the etching of one or both of the substrates to form grooves instead of by deposition.
vi. The spacer height may range from about 1 nm to many microns.
vii. The substrates may be bonded by pressure bonding or by the use of adhesives, such as cyanoacrylics.
viii. The dimensions of the overall structure may be varied from the distance between a single pair of spacers and conductor/nonconductor region to large plates that are many meters in width.
ix. The individual devices may be sandwiched together to form thick structures. For example, in place of a 250 micron thick substrates, sheets having a thickness of about 50 microns or far less may be used to form a thick structures of approximately 250 microns.
x. The working fluid may be selected from a variety of gases, in addition to the noble gases, so that all mentions of gas atoms may be extended to molecules of various types.
xi. The working fluid may be a liquid, as has been described in a prior section, so all mentions of gases and gas atoms may be extended to liquids of various types. For operation within temperature of approximately of 100° C., one possible liquid is ethylene glycol. For high temperature operation, the liquid may be sodium.
xii. Micro-motors formed using micro-electro-mechanical systems (MEMS) technology, or laboratory or industrial sized pumps may be used to pump the gas through the channels.
xiii. The water bath may be replaced with any other material or device that absorbs substantially the released energy wavelengths. Such materials include glass, organic polymers, various thermoelectric devices, one non-limiting example of which comprises a sintered porous skutterudite, thermophotovoltaic devices, thermophotonic devices, and other materials known to those skilled in the art.
xiv. Rather than surrounding the entire apparatus, the absorbing material may be placed in the apparatus, for example, by coating the molded or drilled components, among many possibilities known to those skilled in the art.

### Casimir Cavity Formation Using Submicron Porous Filter Materials and Porous Membranes

Another embodiment of the present invention comprises the use of submicron porous filter materials capable of withstanding high temperatures.

### Examples of such materials include without limitation

a. ceramics—metallic doped; metallic coated;
b. glass—metallic doped; metallic coated;
c. polymers—metallic doped; metallic coated;
d. graphene—metallic doped; metallic coated; and
e. crystal nanotubes—metallic or metallic doped; metallic coated.

These materials may be fabricated using a web printing process, such as a roll-to-roll process, a process which is well-known in the prior art. Openings having a pore size suitable for a maximum Casimir Effect may be produced using compact arrays of a laser or other source of pinpoint high energy, as known to those skilled in the art. For filter materials comprising metals, or metals that are resistant to laser energy, openings of a defined pore size may be prepared using a source of a high energy plasma.

Layers of these filter materials may then be stacked up to produce an array of Casimir cavities of required height. Alternating layers of conducting and non-conducting materials are chosen to imbue the Casimir cavities with the characteristics necessary for quantum vacuum energy extraction.
a. Components used for embodiments may be shaped, molded or bent to maximize application dimensional space requirements and Quantum Vacuum Energy Extraction.
b. Sheets of thermoelectric materials, of which sintered porous skutterudites are a non-limiting example, or other thermoelectric devices may be layered among or around conducting and non-conducting layers of a sintered array assembly for direct heat to electrical conversion.

One commercial source of sintered metal components is GKN Sinter Metals Filters GmbH (Radevormwald, Germany), which manufactures porous metal components of defined pore sizes, and which components can be utilized for filters, filter components, filtration membranes and flow restrictors. Other non-limiting sources of sintered metal filters include Allied Group (Mendham N.J.), Mott Corporation (Farmington Conn.) and Parker Hannifin Corporation.

### Porous Membrane

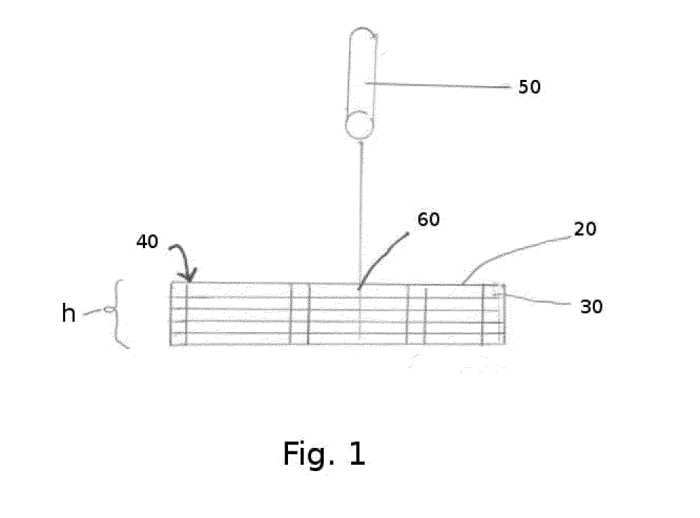

Still another embodiment of this invention comprises Casimir cavities fabricated from porous membranes, an exemplary device of which is shown in FIG. 1. A plurality of layers of conducting material 20 is interspersed with a plurality of strips of a non-conducting material 30, and the number of layers is formed so as to reach a specified height, h. Depending upon the ultimate height of the device to be obtained, it may be necessary to combine a number of stacks 40 upon each other to achieve the ultimate height U.

After the conducting and non-conducting materials are prepared to height h, pores are then made in the stack by exposing the stack 40 to a laser 50 which emits a beam sized to produce a specific pore size 60 in the sheet. The pore size can vary from a range of about 0.1 nanometer (“nm”) up to several millimeters (“mm”), so as to provide for maximum Casimir effect energy extraction. In embodiments, the pore size can vary from a range of about 0.1 nm to 1 mm. In other embodiments the pore size can vary from a range of about 0.5 nm to 500 nm. In other embodiments the pore size can vary from a range of about 0.5 nm to 5 nm.

### Casimir Cavity Formation Using Mesh or Foil Layers

An alternate embodiment of the present invention comprises a three-dimensional structure comprising a stack of thin layers of either or both of a metallic mesh filter, or a metallic foil, each of which contains Casimir sized openings dependent upon the fineness of the mesh weave. Suitable materials for these layers may include, without limitation:
a. metal mesh;
b. a foil or a metal mesh weave that includes a plurality of “bumps” where the woven pieces cross within the mesh. The “bumps” help provide non-conducting spacing between the layers.
c. a foil with alternating layers stacked upon each other during the manufacturing process:
   (i) a conducting layer of appropriate thickness and comprising a plurality of openings or holes for the Casimir cavity effect; and
   (ii) a non-conducting layer of appropriate thickness and porosity.

These methods are adaptations of methods well-known in the prior art for other uses and applications, and that are well developed, time tested, and cost effective.

The foil or mesh weave stack filter described above comprises a plurality of alternating conducting and non-conducting regions comprising layers or sheets of metal, metallic foil, mesh, or other suitable materials. Non-limiting examples of conducting materials include aluminum, copper, platinum, gold, silver, metallically doped ceramics or glass, and metallically coated ceramics or glass, foils and/or mesh. Non-limiting examples of non-conducting materials include silicon, glass, ceramic, and plastic.

Each conducting layer is fabricated from mesh weave of sufficient thickness to effect conduction. Within the weave is a plurality of holes or openings of appropriate size to act as a Casimir cavity and to allow the gaseous medium to pass through. Alternatively, each conducting layer of metal or metallic foil is of sufficient thickness to effect conduction. The metal or metal foil is perforated with arrays of holes or openings of appropriate size to act as a Casimir cavity and to allow the gaseous medium to pass through. In certain embodiments, the holes may be of sub-micron size. In certain embodiments, the holes may be of nanometer size. In other embodiments, the holes may be of micron size and larger. In other embodiments, the holes may be of millimeter size and larger.

The holes may be drilled by arrays of lasers 50 (see FIG. 1), one laser and many splitters, or other methods known in the prior art.

Each non-conducting layer is of the complementary construction of the conducting layer. Thus, if the conducting layer is made of mesh weave, the non-conducting layer may be a metal or metallic foil; if the conducting layer is made of foil, the non-conducting layer may be a mesh weave. Further, the holes in each non-conducting layer are larger than the maximum width to effect vacuum energy extraction, thereby preventing vacuum energy extraction from occurring in the non-conducting layers.

The bumps on each weave layer should be on both sides of that layer to act as spacers to separate that layer from the adjoining layers above and below it. The bumps are sized to leave a sufficient space between adjacent layers to facilitate the conduction/non-conduction effect, thereby increasing the efficacy of the Casimir device.

Such foil stack filters may be fabricated with continuous web or continuous weave manufacturing processes which are known in the art. In this embodiment, the foil openings are prepared to Casimir cavity depth by laser drilling or other hole-creation methods known in the art. The thickness of the foil thereby defines the depth of the Casimir cavity.

Alternatively, a foil with Casimir cavity sized openings may be fabricated with stamping processes which are known in the art. In this stamped foil embodiment, the foil openings are prepared to Casimir cavity depth by stamping. The thickness of the foil thereby defines the depth of the Casimir cavity.

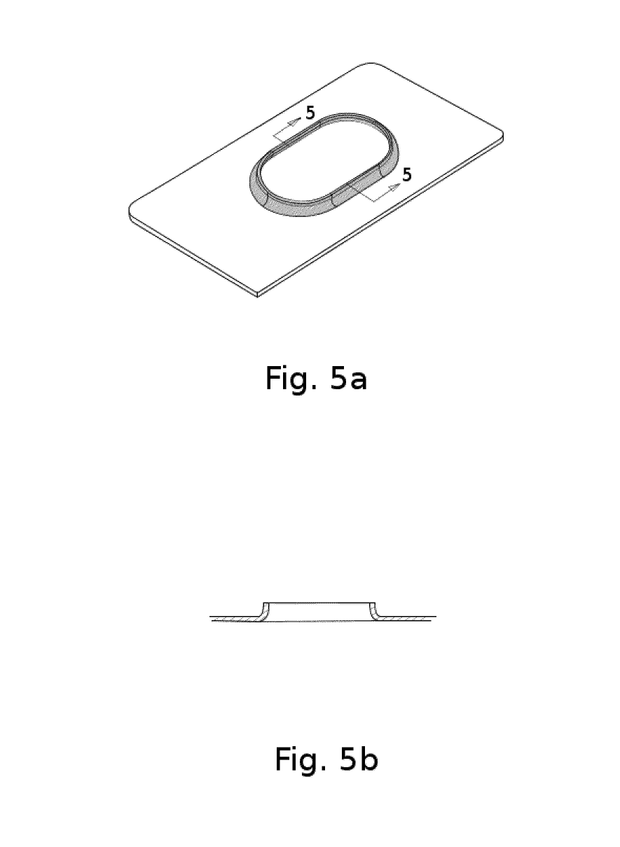

A preferable stamped foil embodiment comprises using a thin foil. Further, preferably the openings through the foil would have one end flat-faced against one surface of the foil and the other end flanged outward along the opposite surface of the foil (see FIG. 5). This type of construction may be seen in the art in internal support members of aircrafts. In this embodiment, the combined thickness of the foil and flange defines the depth of the Casimir cavity.

A foil stack filter may be a 3-dimensional structure containing multiple Casimir cavities, ready for use in quantum vacuum energy extraction.

The foils or meshes may be supported on a substrate that may be an insulating or a partially conducting material, such as, for example only, silicon, glass, ceramic, plastic or the like.

Mesh weave stack filters may be fabricated with continuous web or continuous weave manufacturing processes which are known in the art. In this embodiment, the thickness of the mesh thereby defines the depth of the Casimir cavity.

A mesh weave stack filter may be a 3-dimensional structure containing multiple Casimir cavities, ready for use in quantum vacuum energy extraction.

The meshes may be supported on a substrate that may be an insulating or a partially conducting material, such as, for example only, silicon, glass, ceramic, plastic or the like.

For both the foils and meshes, the conducting layer may be formed from other conductors, such as, for example only, copper, aluminum, gold, silver, silicides, transparent conductors such as indium tin oxide, and the like.

The conducting layer may be recessed within the substrate, or may be layered upon the substrate.

The individual units may be layered or stacked upon each other to form thick structures. For example, instead of stacking a plurality of foils or meshes that are each, for example only, 250 micron thick, smaller sheets having a thickness of, for example, 50 microns or less may be stacked so that dense structures are formed. Similarly, the foils or meshes may have thicknesses ranging from the millimeter range and higher, depending upon the ultimate size of the device.

The fluid for use in the Casimir devices may be selected from a variety of gases, including noble gases, as described in a previous section, such that all reference to gas atoms includes gas molecules.

The fluid may be a liquid, such that all reference to gases and gas atoms may be expanded to include liquids of various types, as has been described previously. For operations within a temperature of about 100 degrees C., ethylene glycol is a potential liquid that may be used. Liquid sodium may be used for higher temperature operations.

Depending upon the ultimate size of the Casimir device that is being constructed, such as sub-micron, or larger, the fluid may be pumped through the channels in the device using a micro-motor manufactured using micro-electrical mechanical systems (“MEMS”) technology, or by conventional pumps utilized for pumping fluid through laboratory or industrial sized apparatus.

### Conducting Layer Comprising Transparent Conductors

Indium tin oxide (“ITO”) is an exemplary transparent conductor. A transparent conductor is generally described as a transparent, electrically conductive film, and is known to those skilled in the art. Transparent conductors were initially used to make energy-conserving windows because of their ability to reflect thermal infrared heat, but now have a variety of uses. Transparent conductors have been used in products such as solar cells, flat panel displays, automatically dimming rear-view mirrors for vehicles, vehicle window defrosters and radio antennas and other applications (see Gordon, MRS Bulletin August 2000).

Transparent conductors havesynthesized been utilizing semiconducting oxides of tin, indium, zinc and cadmium, or from metals such as gold, silver, and titanium nitride. The choice of starting material for a transparent conductor depends upon factors such as the desired conductivity; thickness; the physical, chemical and thermal durability desired; uniformity; toxicity; deposition temperature and cost. Graphene has been reported to be a potentially useful substance for preparing transparent conductors.

Glass plates were initially used to support transparent conductors; thin polymeric films have replaced glass plates. The ITO products are commonly supported on a matrix of polyethylene terephthalate (“PET”) and often referred to as ITO/PET products. The ITO products are commonly used in consumer electronic products, such as flat panel displays and touch screens.

The 3M Company has recently published a technical brochure describing new transparent conductors having a resistance which is claimed to be orders of magnitude lower than those of the ITO/PET materials currently in use. Although these products are suggested for use in touch screens such as smart phones, computer screens, liquid crystal display (“LCD”) televisions, industrial controls and military applications, and are capable of being bent around curved surfaces if needed, they may be utilized as a matrix for a Casimir-cavity containing device.

The conductive material to be used in a Casimir device may be selected from one or more of the transparent conductors, formed, shaped or bent to a size suitable for use in the Casimir device.

### Nanotube Arrays

Carbon nanotubes have been known since at least 1991, and have been utilized in a variety of applications, often trying to take advantage of their high tensile strength. Another embodiment of this invention comprises Casimir cavities formed using arrays of nanotubes made from carbon or other materials, such as described in Schlittler, R. R., et al., 2001, “Single Crystals of Single-Walled Carbon Nanotubes Formed by Self-Assembly” Science Magazine, May 11, 2001, 1136-39.

Carbon nanotubes are commercially available, and a plurality of carbon nanotubes, either as a specific quantity (by weight) or by number of nanotubes, may be positioned in a container. The nanotubes to be used may be selected from either single-walled nanotubes, or multi-walled nanotubes, or a mixture thereof, to form the conducting component of the Casimir device.

Single walled carbon nanotubes that have either semiconducting or metallic properties have been reported in the literature, suggesting that one or more dopants can be added into the nanotube structure prior to their use in various applications.

Carbon nanotubes and/or carbon nanofibers have been modified and prepared as a material that has been designated as buckypaper. This material has been reported to be about 25 nanometers thick, having both thermal and electric conductivity properties, and a high mechanical strength and strain rate. Some proposed uses for buckypaper have included electromagnetic interference shielding, radiation shielding, heat sinks, ultra-high strength structures, such as body armor, and components of computer monitors. Embodiments of buckypaper may be utilized as the conductive component of a Casimir device.

### Casimir Devices Utilizing Wire

In this embodiment 100, a plurality of wires 110 may be bundled together and held together by a form fitting filter shell of conducting material 120 such that the fluid is forced through the conducting and non-conducting component.

The wires 110 may a have cross-section that is circular (round) or otherwise shaped as desired.

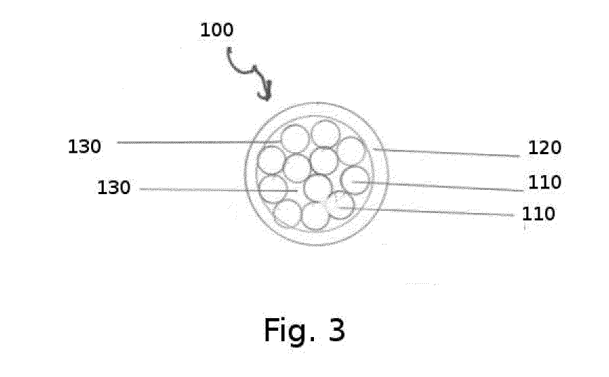

Because gaps will exist between the wires 110, even when packed together, the gaps 130 provide a channel through which gas can flow, and thereby effect a Casimir device (FIG. 3). The wires utilized may be commercially available wires having a narrow diameter, or wires extruded, drawn, rolled, spun, molded, or stamped to have thicknesses/diameters at either the sub-micron, micron, or millimeter size. The wires may be manufactured from any conducting material, such as, but not limited to aluminum, copper, silver, metallically doped or metallically coated non-conducting wire material. Non-conducting wires can be similarly prepared from a variety of non-conducting materials. As an example, glass or polymer filaments may be potential “wires” for use in this type of device.

In this embodiment, the bundled wires may be used as Casimir devices in the manner described for previous embodiments. By modifying a non-conducting material with a conductive material and producing a conductive material, the resulting conductive product may reduce the amount of metal needed to manufacture a Casimir device.

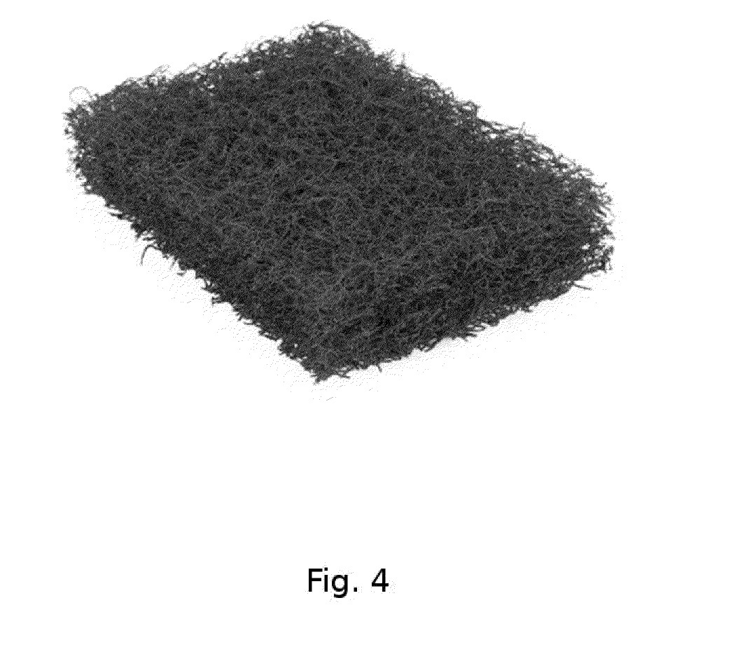

In addition to the wire bundles illustrated in FIG. 3, wires may also be in one or more non-linear arrays (see FIG. 4).

### Casimir Devices Utilizing Hollow Tubes

In this embodiment 200, a plurality of hollow tubes 210 may be bundled together and held together by a form fitting filter shell 220 of conducting material such that the fluid is forced through the conducting and non-conducting component.

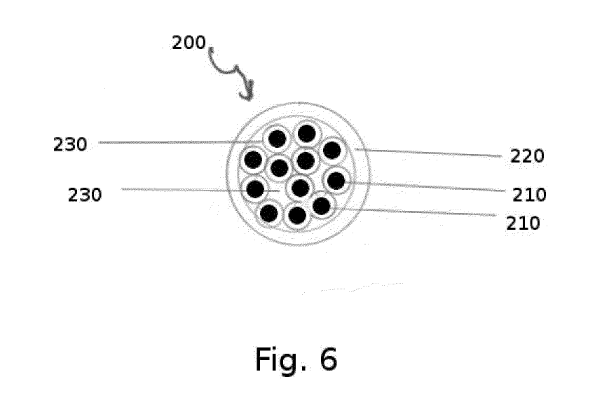

Because gaps 230 will exist between the tubes, even when packed together, the gaps 230 provide a channel through which gas can flow, and thereby effect a Casimir device (see FIG. 6). The tubes 210 utilized may be commercially available tubes having a narrow diameter, or tubes produced by one or more prior-art processes similar to those described above for wires, as appropriate. The tubes 210 may have outer diameters at either the sub-micron, micron, or millimeter size. The tubes 210 may be manufactured from any conducting material, such as, but not limited to aluminum, copper, silver, metallically doped or metallically coated non-conducting material. Non-conducting tubes can be similarly prepared from a variety of non-conducting materials. As an example, glass or polymer filaments may be potential “tubes” for use in this type of device.

In this embodiment 200, the bundled tubes may be used as Casimir devices in the manner described for previous embodiments. By modifying a non-conducting material with a conductive material and producing a conductive material, the resulting conductive product may reduce the amount of metal needed to manufacture a Casimir device.

Because these tubes 210 are hollow, the fluid flow may be both outside and inside the bundled tubes.

### Casimir Devices Comprising Graphene

Graphene is a monoatomic layer of carbon, commonly prepared by scraping a piece of graphite on a surface, or by the splitting of carbon nanotubes. Carbon nanotubes have been reported to have semi-conducting or metallic components, as described in a prior section. Since carbon nanotubes are a source of graphene, since carbon nanotubes can be prepared with a dopant to alter their properties, a similarly modified graphene should be obtainable from such modified carbon nanotubes. It should be possible to produce graphene by roll-to-roll web processing in the near future.

Interspersing a plurality of layers of a non-conducting material, such as those described in other embodiments in this specification, between a plurality of graphene or modified graphene layers can be used to prepare Casimir cavities.

The resulting block of graphene strips may then be subjected to laser treatment in order to create channels through which gas would be able to flow through in the block. The device may then be positioned in contact with conducting materials, enclosed in a container, and used for generation of heat from the resultant Casimir device. Multiple blocks may be stacked to form increasingly larger matrices for the Casimir device, as described in a prior section.

### Three-Dimensional Prototyping Methods

Embodiments of the present invention may utilize three-dimensional prototyping methods for the manufacture of Casimir cavity-containing devices. These methods use a process similar to inkjet printing to deposit layers of material on top of each other in the desired configuration, thereby building up an appropriately shaped three-dimensional structure. Generally, the process is based upon input from a prototype developed using Computer-Aided Design (“CAD”) software. The prototype may be prepared utilizing one of a number of commercially available software programs, a non-limiting example of such programs being AUTOCAD® (Registered trademark of Autodesk, Inc, San Rafael, Calif.).

A number of 3-dimensional printing and/or prototyping devices are commercially available, and may be utilized to build devices for energy generation. Some non-limiting examples are devices manufactured by companies such as 3-Dimensional Services Group (Rochester, Mich.), 3-D Systems, Inc. (Rock Hill, S.C.), or Objet, Ltd. (Billerica, Mass.).

Processes utilizing Computer Numeric Control (“CNC”) devices may also be utilized for prototyping and/or fabrication. As known to those skilled in the art, utilization of a particular apparatus and prototyping protocol is dependent upon the materials being employed for manufacture of the energy generating device.

### Charged Particle Deposition

Still another embodiment of this invention comprises fabricating Casimir cavities by charged particle deposition. This method uses a process similar to the technique commonly used in painting automobiles or electroplating to deposit layers on an appropriate substrate, in which an electric charge is applied to the surface to be painted or coated, and the coating is then applied to the charged surface.

In this embodiment, the components of the coating have a charge opposite to that of the charged surface, thereby adhering to the charged surface. Without limitation, this coating processes may be accomplished through air, through a liquid or solution, or across a vacuum, all by techniques known in the art. By controlling the thickness of this deposition, and the use of conductive and non-conductive coatings on the surface, arrays containing Casimir cavities may be fabricated.

It is known that some of the fabrication processes described above result in uniform-sized conducting cavities, while other processes produce non-uniformed sized conducting cavities. The uniformity or non-uniformity of the conducting cavities is not a critical factor, provided that all cavities in the conducting region do not exceed the size requirements needed to function as Casimir cavities in quantum vacuum energy extraction.

Manufacturing of the structures may be accomplished using standard techniques for forming microstructures, nanostructures and integrated circuit articles by employing chemical deposition and etching in conjunction with photoresist or photo-making preparations, or by vacuum film-deposition or similar methods, such as, but not limited to, oxidation, precipitation or sputtering, on a standard conducting or superconducting layer. The conducting or superconducting layer can be deposited or formed atop various types of rigid substrate-base materials, including diamond, glass, metallic oxides, polymers, silicon carbides, silicon oxides, sapphires, semiconductors, related materials and combinations thereof.

### Polymers

The term “polymer” has been utilized throughout this specification, and defined as a
large molecule formed by the union of at least five identical monomers; it may be natural, such as cellulose or DNA, or synthetic, such as nylon or polyethylene; polymers usually contain many more than five monomers, and some may contain hundreds or thousands of monomers in each chain. Academic Press Dictionary of Science and Technology, 1992, p. 1691, Academic Press, New York.

However it is to be understood that in addition to this definition, polymers may be formed from nonidentical monomers.

Some examples of synthetic polymers include, but are not limited to, polyethylene, polypropylene, polyvinyl chloride, polystyrene, polyisopropylene, polkytetrafluoethylene (“PTFE”, sold under the trademark TEFLON®, registered trademark of E.I. DuPont Co.), polyvinyl acetate, poly methyl methacrylate, poly ethyl methacrylate and polyethylene terephthalate, polyamides, polycarbonates and the like. Many of these synthetic polymers are thermoplastic materials, and additional exemplary polymers may include thermoset polymers such as formaldehyde-based compounds as phenol-formaldehydes, urea-formaldehydes, melamine formaldehydes and the like.

Thus, with this invention, there are commercially viable systems and methods for tapping into the significant amounts of energy theoretically available from quantum vacuum energy or zero-point radiation fields.

It is to be understood that all embodiments of apparatus for generating quantum energy extraction are operably coupled with means for removing the extracted energy from the apparatus. Preferably, tubing or passages containing a circulating heat transfer substance passes through the apparatus. In one embodiment, these passages may be baked into sintered cavities during fabrication. In another embodiment, these passages may be inserted into the cavities after fabrication is complete. For example, without limitation, small diameter tubing may be passed through laser-created passages in the apparatus. Larger diameter tubing may be passed through passages drilled through the apparatus.

Alternatively, the apparatus may be enclosed in a container that includes at least a heat transfer substance.

All of these setups function analogously to prior art radiators. All of these heat transfer techniques are known in the art. In addition, other known means and methods of heat transfer may also be employed; for example, such techniques are discussed in the '286 patent.

The extracted heat is then available for use as energy, utilizing techniques known in the art.

Further, it to be understood that non-conducting regions need not be solid. They may also be hollow, tube-like structures sufficiently strong and configured so that the fluid can pass through, such as high-pressure, high-temperature piping.

Although this invention has been described with a certain degree of particularity, it is to be understood that the present disclosure (including, without limitation, all drawing pages) has been made only by way of illustration, and that numerous changes in the details of the system, apparatus, and/or method may be resorted to without departing from the spirit and scope of the invention.

I claim:

1. A method for preparing a device for quantum vacuum energy extraction comprising:
providing a fluid which obtains electromagnetic energy from an ambient electromagnetic quantum vacuum while within the ambient electromagnetic quantum vacuum;
providing a first member comprising at least one Casimir cavity configured to cause the fluid to release at least some of the energy when the fluid is passed into the Casimir cavity;
providing a second member comprising a mechanism cooperatable with the first member so as to cause the fluid to pass from the ambient electromagnetic quantum vacuum into the Casimir cavity and then out of the Casimir cavity and back into the ambient electromagnetic quantum vacuum;
positioning the second member in the ambient electromagnetic quantum vacuum,
passing the fluid into and out of the Casimir cavity by relative movement between the Casimir cavity and the fluid;
providing a third member comprising an energy capture mechanism to capturing at least some of the released energy, the capture mechanism; and
positioning the third member in proximity to the Casimir cavity such that at least some of the released energy is captured by the capture mechanism.

2. The method as described in claim 1, wherein the first member providing step comprises utilizing a submicron porous filter as the first member.

3. The method as described in claim 1, wherein the first member providing step comprises positioning a plurality of conducting means and a plurality of non-conducting means with respect to each other such that the Casimir cavity is formed therebetween.

4. The system as described in claim 2, wherein the first member further comprises one or more members chosen from the group consisting of a porous membrane, a porous filter, a sintered filter, a metal wire, a metal tube, a metallic mesh, and a metallic foil.

5. The method as described in claim 3, wherein the conducting materials are chosen from one or more materials chosen from the group consisting of a graphene, a ceramic, a glass, a polymer, a crystal nanotube, a carbon nanotube, a metallic mesh, a metallic foil, and a transparent conductor.

6. The method as described in claim 5, wherein the conducting materials comprises one or more materials chosen from the group consisting of metallically-doped graphene and metallically-coated graphene.

7. The method as described in claim 5, wherein the conducting material further comprises one or more materials chosen from the group consisting of a metallically-doped ceramic, a metallically-doped glass, a metallically-doped polymer, a metallically-doped crystal nanotube, a metallically-doped carbon nanotube, a metallically-coated ceramic, a metallically-coated glass, a metallically-coated polymer, a metallically-coated crystal nanotube, and a metallically-coated carbon nanotube.

8. The method as described in claim 5, wherein the first member is fabricated utilizing a charged-particle process.

9. The method as described in claim 5, wherein the first member is fabricated utilizing a three-dimensional prototyping device.

10. The method as described in claim 9, wherein the three-dimensional prototyping device is an inkjet printer.

11. The method as described in claim 9, wherein the three-dimensional prototyping device is a computer numeric controlled device.

12. The method as described in claim 9, wherein the first member is fabricated using a web roll-to-roll process.

13. The method as described in claim 12, wherein the first member providing step further comprising the step of creating a plurality of openings within the first member, the plurality of openings having a size suitable for maximum Casimir energy generation.

14. The method as described in claim 13, wherein the openings have a size ranging from about 0.5 nanometers (“nm”) to about 5 millimeters (“mm”).

15. The method as described in claim 13, wherein the fabricating step further comprises stacking a plurality of conducting materials on top of each other to a specified height.

16. The method as described in claim 1, wherein the first member providing step comprises a process chosen from the group consisting of sintering, metal spraying and metal injection molding.

17. A system for extracting and collecting electromagnetic energy from an ambient electromagnetic quantum vacuum, the system comprising:
a first member comprising a conducting means and a non-conducting means, the conducting means and the non-conducting means positioned with respect to each other such that a Casimir cavity is formed therebetween, the first member configured to cause a fluid containing electromagnetic energy obtained from the ambient electromagnetic quantum vacuum to release at least some of the energy when the fluid is passed into the Casimir cavity;
a second member for removal of the electromagnetic energy released by the fluid and captured by the means for absorbing energy, the second member comprising a container, positioned in the ambient electromagnetic quantum vacuum and including a source of the fluid and a mechanism cooperating with the first member so as to cause the fluid to pass from the ambient electromagnetic quantum vacuum into the Casimir cavity and then out of the Casimir cavity and back into the ambient electromagnetic quantum vacuum, whereby the fluid when passing into the Casimir cavity releases at least some of its energy and then, upon passing back into the ambient electromagnetic quantum vacuum, again takes in electromagnetic energy from the ambient electromagnetic quantum vacuum, the second member and the first member cooperating with one another such that the fluid passes out and into the Casimir cavity by relative movement between the Casimir cavity and the fluid; and
a mechanism for capturing at least some of the electromagnetic energy released by the fluid, the mechanism for capturing including a means for absorbing energy, the means for absorbing energy positioned in proximity to the Casimir cavity such that at least some of the electromagnetic energy released by the fluid is captured by the means for absorbing energy.

18. The system as described in claim 17, wherein the first member further comprises one or more members chosen from the group consisting of a porous membrane, a porous filter, a sintered filter, a metal wire, a metal tube, a metallic mesh, and a metallic foil.

19. The system as described in claim 17, wherein the conducting means comprises graphene.

20. The system as described in claim 17, wherein the conducting means comprises buckypaper.
